(19) United States
(12) Patent Application Publication
(10) Pub. No.: US 2024/0087891 A1
(43) Pub. Date: Mar. 14, 2024

(54) Method for Processing a Substrate

(71) Applicant: Tokyo Electron Limited, Tokyo (JP)

(72) Inventors: Eric Chih-Fang Liu, Albany, NY (US); Shihsheng Chang, Albany, NY (US); Kai-Hung Yu, Albany, NY (US); Yun Han, Albany, NY (US)

(21) Appl. No.: 17/931,838

(22) Filed: Sep. 13, 2022

(51) Int. Cl. H01L 21/033; H01L 21/311; H01L 21/768

(52) U.S. Cl. CPC H01L 21/0337; H01L 21/0332; H01L 21/31144; H01L 21/76802

(57) ABSTRACT

A method of patterning a substrate includes forming a first line, a second line, and a third line over the substrate, the first line, the second line, and the third line being parallel in a plan view, and forming a fourth line and a fifth line over the first line, the second line, and the third line, the fourth line and the fifth line being orthogonal to the first line in the plan view. The method further includes etching a hole through the second line using the first line, the third line, the fourth line, and the fifth line as an etching mask, and filling the hole with a dielectric material to form a block.

### TECHNICAL FIELD

The present invention relates generally to a method for processing a substrate, and, in particular embodiments, to a method of patterning a layer with self-aligned blocks.

### BACKGROUND

Generally, a semiconductor device, such as an integrated circuit (IC) is fabricated by sequentially depositing and patterning layers of dielectric, conductive, and semiconductor materials over a substrate to form a network of electronic components and interconnect elements (e.g., transistors, resistors, capacitors, metal lines, contacts, and vias) integrated in a monolithic structure. Process flows used to form the constituent structures of semiconductor devices often involve depositing and removing a variety of materials while a pattern of several materials may be exposed in a surface of the working substrate.

The minimum dimension of features in a patterned layer is shrunk periodically to roughly double the component density at each successive technology node, thereby reducing the cost per function. Innovations in patterning, such as immersion deep ultraviolet (i-DUV) lithography, multi patterning, and 13.5 nm wavelength extreme ultraviolet (EUV) optical systems have brought some critical dimensions down to near ten nanometers. This squeezes the margin for pattern misalignment (e.g., Total Edge Placement Error) and leads to, for example, stricter overlay requirements in multi patterning for advanced technology nodes (7 nm and below). As such, innovative process flows are useful for reducing pattern misalignment.

### SUMMARY

In accordance with an embodiment, a method of patterning a substrate includes: forming a first line, a second line, and a third line over the substrate, wherein the second line is between the first line and the third line, wherein the first line and the third line are a first material, wherein the second line is a second material, the second material being different from the first material, and wherein the first line, the second line, and the third line are parallel in a plan view; forming a fourth line and a fifth line over the first line, the second line, and the third line, the fourth line and the fifth line being orthogonal to the first line in the plan view, wherein the fourth line and the fifth line are a third material, the third material being different from the first material and the second material; etching a hole through the second line using the first line, the third line, the fourth line, and the fifth line as an etching mask; and filling the hole with a dielectric material to form a block.

In accordance with another embodiment, a method of patterning a substrate includes: forming a mandrel over a dielectric layer; depositing a first spacer on a first side of the mandrel and a second spacer on a second side of the mandrel, the second side being opposite the first side; forming a metal oxide resist over the mandrel, the first spacer, and the second spacer, the metal oxide resist including a first bar and a second bar, the first bar and the second bar being perpendicular to the mandrel in a plan view; forming a self-aligned block through the mandrel using the first spacer, the second spacer, the first bar of the metal oxide resist, and the second bar of the metal oxide resist as an etching mask; removing the mandrel and the metal oxide resist; patterning the dielectric layer using the first spacer, the second spacer, and the self-aligned block as an etching mask; removing the first spacer, the second spacer, and the self-aligned block; and forming a metallization pattern in trenches between portions of the patterned dielectric layer.

In accordance with yet another embodiment, a method of patterning a substrate includes: forming a first mandrel and a second mandrel over a dielectric layer; depositing a first spacer and a second spacer on opposite sides of the first mandrel and depositing a third spacer and a fourth spacer on opposite sides of the second mandrel; forming a filling layer between the second spacer and the third spacer; forming a metal oxide resist over the first mandrel, the second mandrel, the first spacer, the second spacer, the third spacer, and the fourth spacer, the metal oxide resist including a first bar, a second bar, and a third bar, the first bar, the second bar, and the third bar being perpendicular to the first mandrel in a plan view; forming a first self-aligned block through the filling layer using the second spacer, the third spacer, the first bar of the metal oxide resist, and the second bar of the metal oxide resist as an etching mask; forming a second self-aligned block through the first mandrel using the first spacer, the second spacer, the second bar of the metal oxide resist, and the third bar of the metal oxide resist as an etching mask; and forming a third self-aligned block through the second mandrel using the third spacer, the fourth spacer, the second bar of the metal oxide resist, and the third bar of the metal oxide resist as an etching mask.

It is to be understood that both the foregoing general description and the following detailed description are exemplary and explanatory only and are not restrictive of the disclosure, as claimed.

### BRIEF DESCRIPTION OF THE DRAWINGS

For a more complete understanding of the present invention, and the advantages thereof, reference is now made to the following descriptions taken in conjunction with the accompanying drawings, in which:

FIGS. 1A-13C illustrate plan and cross-sectional views of a semiconductor device at various intermediate stages of fabrication, in accordance with some embodiments;

FIG. 14 illustrates a flow chart for a method of patterning a substrate;

FIG. 15 illustrates a flow chart for another method of patterning a substrate; and

FIG. 16 illustrates a flow chart for yet another method of patterning a substrate.

Corresponding numerals and symbols in the different figures generally refer to corresponding parts unless otherwise indicated. The figures are drawn to clearly illustrate the relevant aspects of the embodiments and are not necessarily drawn to scale. The edges of features drawn in the figures do not necessarily indicate the termination of the extent of the feature.

### DETAILED DESCRIPTION OF ILLUSTRATIVE EMBODIMENTS

The making and using of various embodiments are discussed in detail below. It should be appreciated, however, that the various embodiments described herein are applicable in a wide variety of specific contexts. The specific embodiments discussed are merely illustrative of specific ways to make and use various embodiments, and should not be construed in a limited scope.

According to one or more embodiments of the present disclosure, this application relates to methods of patterning a layer (e.g., an interconnect layer) with self-aligned blocks. Metallization patterns formed with small pitch scaling (e.g., less than 30 nm) may be impacted by edge placement error of dielectric portions between conductive lines of the metallization patterns. Misplaced dielectric portions may overlap the conductive lines and cause yield loss. Edge placement error may be reduced by forming self-aligned blocks using the selectivities of adjacent columns of different materials to restrict the blocks in a horizontal direction as seen in a plan view. The self-aligned blocks may be further restricted in a vertical direction as seen in a plan view by forming rows (also referred to as bars) of a metal oxide resist across the columns of different materials. The crisscross pattern of columns of different materials and rows of the metal oxide resist allows for the formation of fully self-aligned blocks that are restricted in two dimensions. These fully self-aligned blocks can be used to form metallization patterns with small critical dimensions (e.g., less than 15 nm) and reduced edge placement errors.

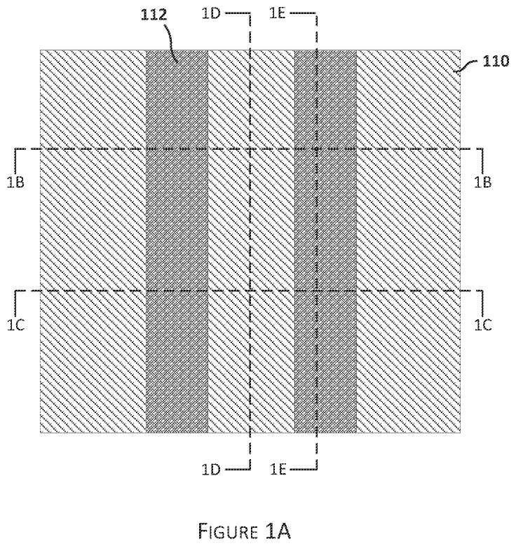

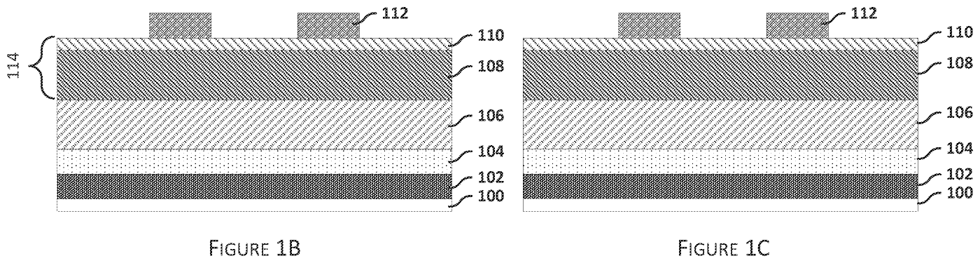

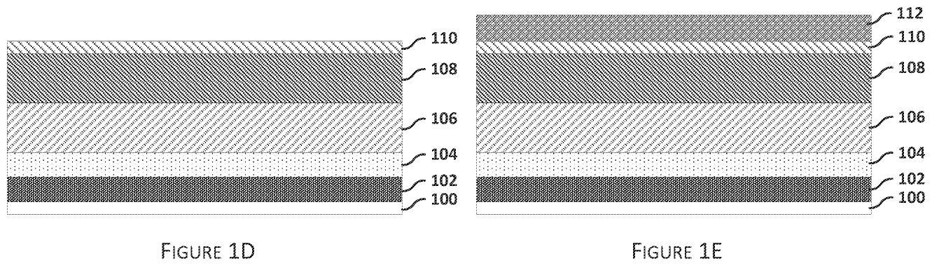

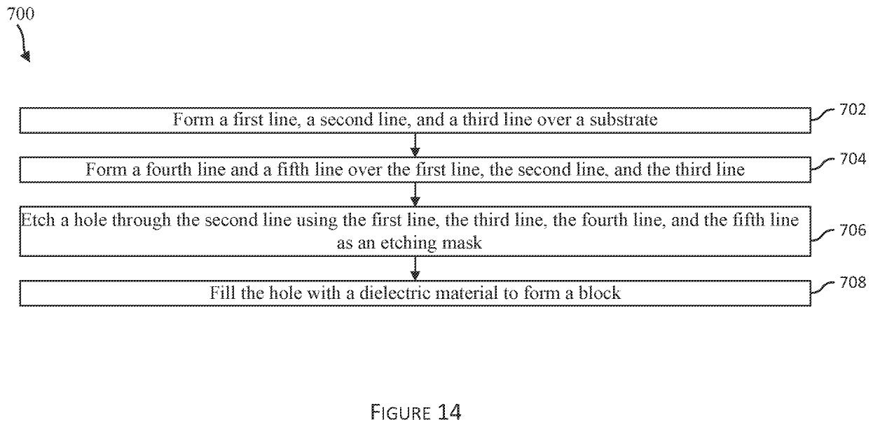

Embodiments of the disclosure are described in the context of the accompanying drawings. An embodiment of an example fabrication process including formations of fully self-aligned blocks will be described using FIGS. 1A-13C. Embodiments of methods for patterning substrates will be described using FIGS. 14, 15, and 16.

FIGS. 1A-1E illustrate a plan view and respective cross-sectional views of a semiconductor structure, in accordance with some embodiments. FIG. 1B is illustrated in a cross-sectional view along line 1B-1B in FIG. 1A, FIG. 1C is illustrated in a cross-sectional view along line 1C-1C in FIG. 1A, FIG. 1D is illustrated in a cross-sectional view along line 1D-1D in FIG. 1A, and FIG. 1E is illustrated in a cross-sectional view along line 1E-1E in FIG. 1A.

The semiconductor structure illustrated by FIGS. 1A-1E includes a substrate 100, a target layer 102 over the substrate 100, a hardmask layer 104 over the target layer 102, a material layer for mandrels 106 over the hardmask layer 104, and a lithography stack 114 over the material layer for mandrels 106. In some embodiments, the substrate 100 may be a silicon wafer, or a silicon-on-insulator (SOI) wafer. In certain embodiments, the substrate 100 may comprise a silicon germanium wafer, silicon carbide wafer, gallium arsenide wafer, gallium nitride wafer and other compound semiconductors. In other embodiments, the substrate 100 comprises heterogeneous layers such as silicon germanium on silicon, gallium nitride on silicon, silicon carbon on silicon, as well layers of silicon on a silicon or SOI substrate. In various embodiments, the substrate 100 is patterned or embedded in other components of the semiconductor device. In various embodiments, the substrate 100 may be a part of a semiconductor device, and may have undergone a number of steps of processing following, for example, a conventional process. The substrate 100 accordingly may comprise layers of semiconductors useful in various microelectronics. For example, the semiconductor structure may comprise the substrate 100 in which various device regions are formed.

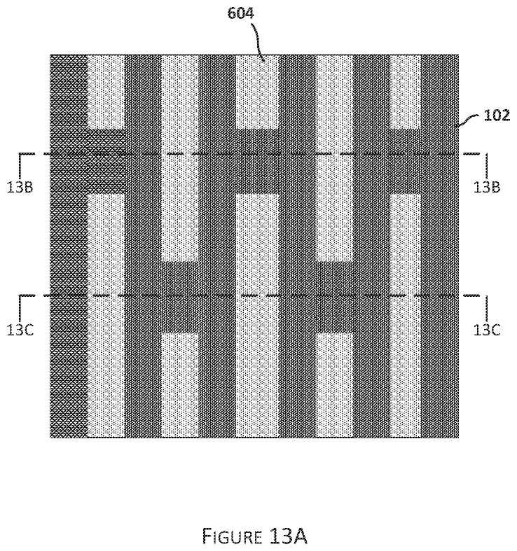

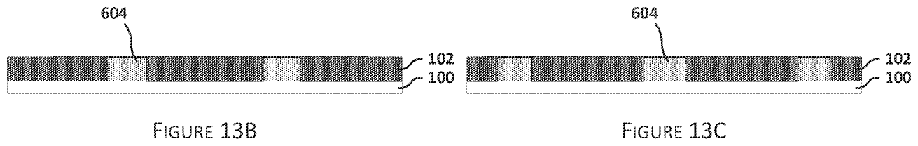

The target layer 102 (also referred to as a dielectric layer) is formed over the substrate 100 and the hardmask layer 104 is formed over the target layer 102. The target layer 102 is the layer to be patterned using the hardmask layer 104 as an etch mask, after the hardmask layer 104 has been patterned using a self-aligned double-patterning technique using fully self-aligned blocks (SABs), as described in further detail below. After being patterned, a metallization pattern is formed in trenches through the target layer 102 (see below, FIGS. 13A-13C). In some embodiments, the target layer 102 is a silicon-based dielectric material with a low dielectric constant (i.e., low-k value) such as organosilicate glass (SiCOH), dense SiCOH, porous SiCOH, and other porous dielectric materials. In some embodiments, the hardmask layer 104 comprises titanium nitride, titanium, titanium oxide, tantalum, tungsten carbide, other tungsten based compounds, ruthenium based compounds, aluminum based compounds, amorphous silicon, silicon nitride, silicon carbide, or the like. However, any suitable materials may be used for the target layer 102 and the hardmask layer 104.

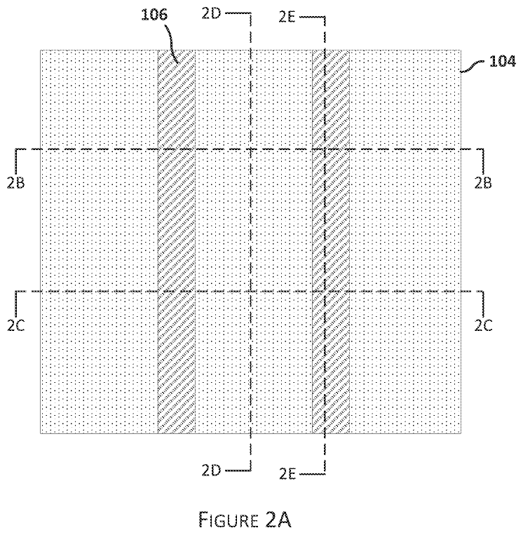

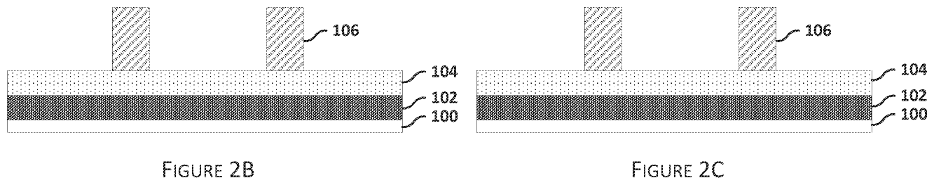

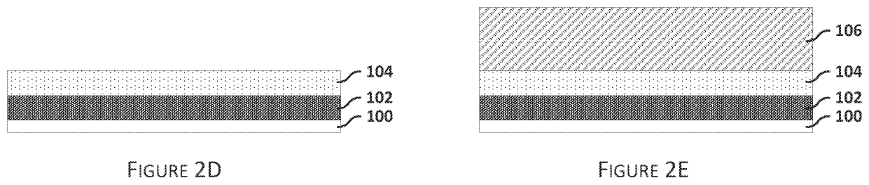

The material layer for mandrels 106 is formed over the hardmask layer 104. The material layer for mandrels 106 will be subsequently patterned to form mandrels 106 (see below, FIGS. 2A-2E). In some embodiments, the material layer for mandrels 106 comprises amorphous silicon, amorphous carbon, metal oxide, metal nitride, metal, or any other type of sacrificial material known within the art. The material layer for mandrels 106 may also compromise a plasma polymerized organic film, spin on film, or dielectric film.

A lithography stack 114 is formed over the material layer for mandrels 106. As illustrated in FIGS. 1B-1E, the lithography stack 114 comprises a planarizing layer 108 over the material layer for mandrels 106 and an antireflective coating 110 over the planarizing layer 108. In some embodiments, the planarizing layer 108 comprises spin-on carbon (SOC), an organic planarizing layer (OPL), amorphous carbon, or the like. In some embodiments, the antireflective coating 110 comprises a bottom antireflective coating (BARC) such as a silicon antireflective coating (SiARC), an organic BARC, SiC, spin-on glass (SOG), silicon, silicon oxide, silicon nitride, or the like. However, any suitable materials may be used for the planarizing layer 108 and the antireflective coating 110.

A patterned resist 112 is formed over the lithography stack 114. The patterned resist 112 is used for the subsequent patterning of the material layer for mandrels 106 (see below, FIGS. 2A-2E). In some embodiments, the patterned resist 112 is a metal oxide resist that is exposed with extreme ultraviolet (EUV) radiation and developed with a wet etch selective to either exposed or unexposed regions of the metal oxide resist. However, any suitable photoresist, exposure method, and development method may be used to form the lithography stack 114.

FIGS. 2A-2E illustrate a plan view and respective cross-sectional views of the semiconductor structure after mandrels 106 are formed, in accordance with some embodiments. FIG. 2B is illustrated in a cross-sectional view along line 2B-2B in FIG. 2A, FIG. 2C is illustrated in a cross-sectional view along line 2C-2C in FIG. 2A, FIG. 2D is illustrated in a cross-sectional view along line 2D-2D in FIG. 2A, and FIG. 2E is illustrated in a cross-sectional view along line 2E-2E in FIG. 2A.

The material layer for mandrels 106 (see above, FIGS. 1A-1E) is patterned to form mandrels 106. Although two mandrels 106 are illustrated in FIGS. 2A-2C, any suitable number of mandrels 106 may be formed. For example, additional mandrels (not illustrated) may be present on the right and left sides of FIG. 2A. In some embodiments, the mandrels 106 are formed with a multi-step etch process. For example, the patterned resist 112 may be used as an etch mask to pattern a portion of the lithography stack 114. The patterned portion of the lithography stack 114 is then used as an etch mask to etch the remaining portion of the lithography stack 114. Next, the remaining portion of the lithography stack 114 is used as an etch mask to form the mandrels 106. After patterning the mandrels 106, the remaining portions of the lithography stack 114 and the patterned resist 112 are removed with a suitable process, such as a CMP or the like.

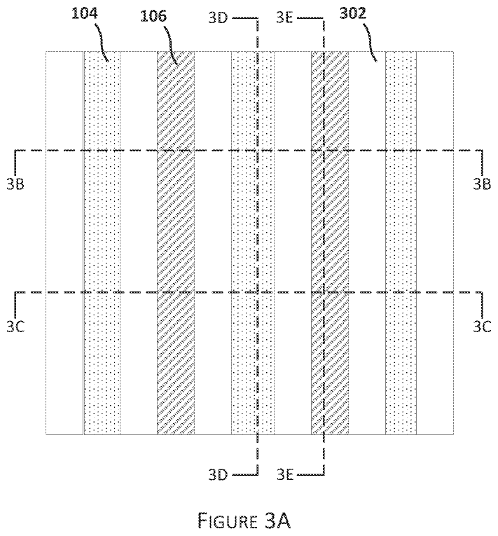

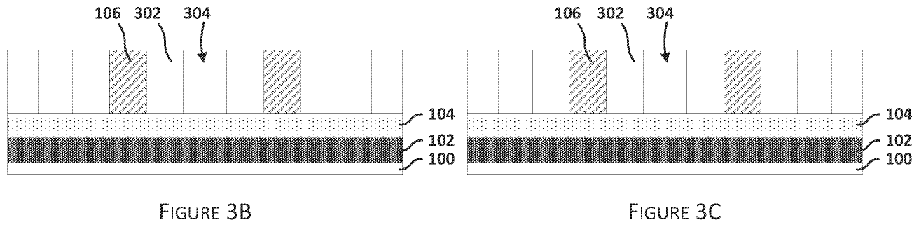

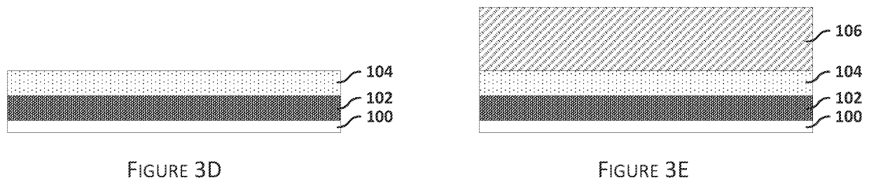

FIGS. 3A-3E illustrate a plan view and respective cross-sectional views of the semiconductor structure after spacers 302 are formed, in accordance with some embodiments. FIG. 3B is illustrated in a cross-sectional view along line 3B-3B in FIG. 3A, FIG. 3C is illustrated in a cross-sectional view along line 3C-3C in FIG. 3A, FIG. 3D is illustrated in a cross-sectional view along line 3D-3D in FIG. 3A, and FIG. 3E is illustrated in a cross-sectional view along line 3E-3E in FIG. 3A.

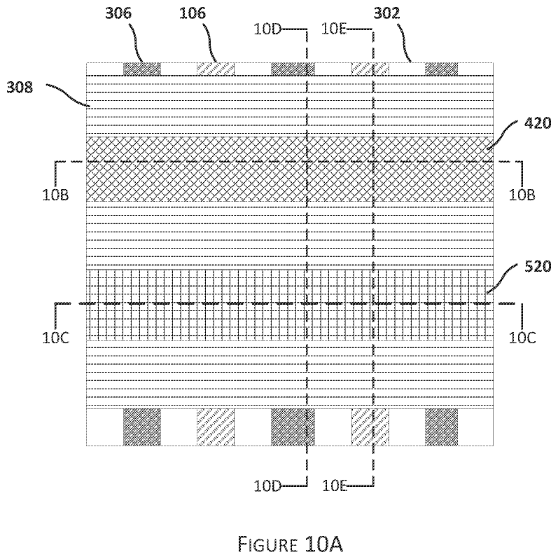

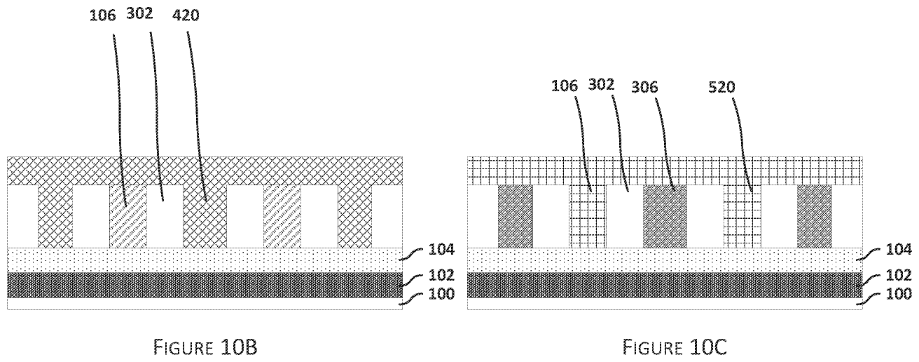

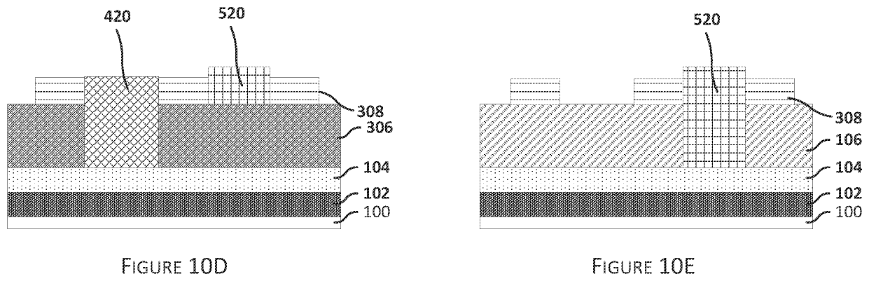

As shown in FIGS. 3A-3C, spacers 302 are formed along sidewalls of the mandrels 106. First trenches 304 are formed between spacers 302 that are adjacent. The spacers 302 may be formed by a conventional self-aligned sidewall spacer technique, where spacer material is deposited roughly conformally over the substrate with a suitable process such as ALD or the like. In some embodiments, the spacer material is an oxide or nitride such as silicon oxide, silicon nitride, titanium nitride, titanium oxide, zirconium oxide, or the like. The spacer material is different from the material of the mandrels 106 so that subsequent etches may be selective to the mandrels 106 over the spacers 302 (see below, FIGS. 10A-10E). The spacer material is selectively etched using an anisotropic etching technique (e.g., a reactive ion etch (RIE)) that clears the tops of the mandrels 106 and removes spacer material from over the hardmask layer 104 between the mandrels 106 to form the spacers 302 and the first trenches 304. FIGS. 3A-3C illustrates spacers 302 formed on the right and left boundaries of the figures. These spacers 302 may be formed on sidewalls of additional mandrels beyond the right and left boundaries of FIGS. 3A-3C.

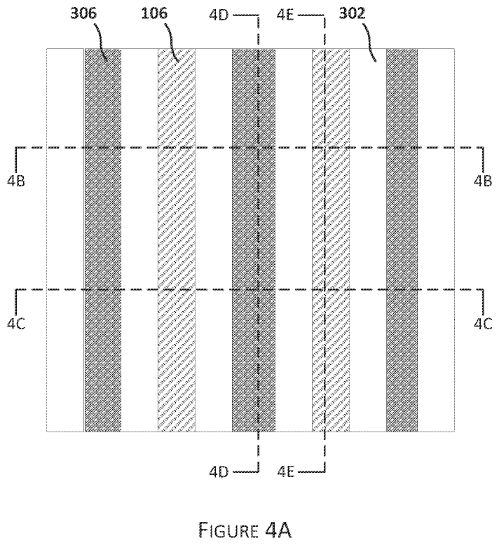

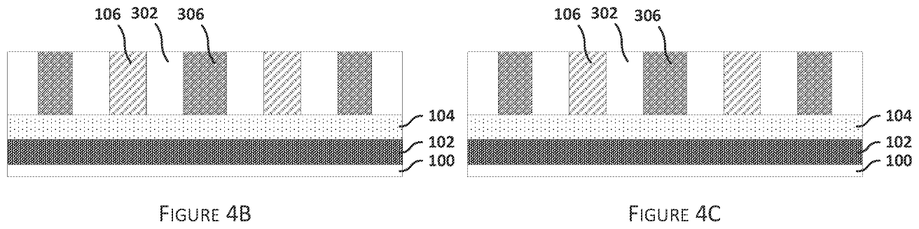

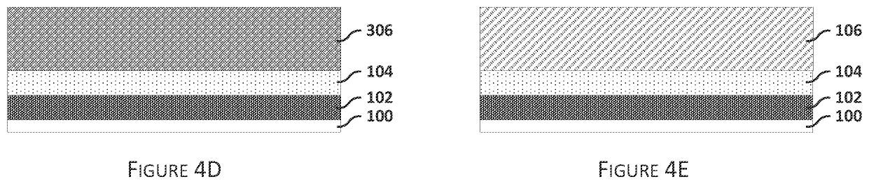

FIGS. 4A-4E illustrate a plan view and respective cross-sectional views of the semiconductor structure after a filling layer 306 is formed in the first trenches 304, in accordance with some embodiments. FIG. 4B is illustrated in a cross-sectional view along line 4B-4B in FIG. 4A, FIG. 4C is illustrated in a cross-sectional view along line 4C-4C in FIG. 4A, FIG. 4D is illustrated in a cross-sectional view along line 4D-4D in FIG. 4A, and FIG. 4E is illustrated in a cross-sectional view along line 4E-4E in FIG. 4A.

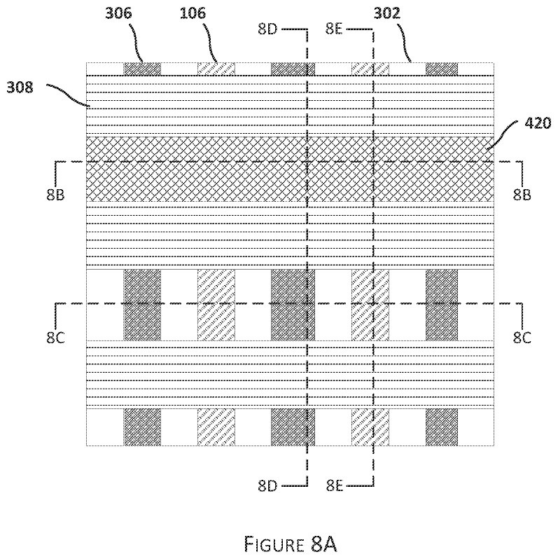

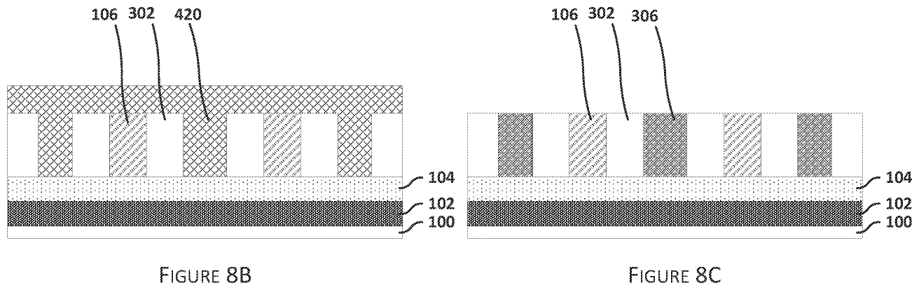

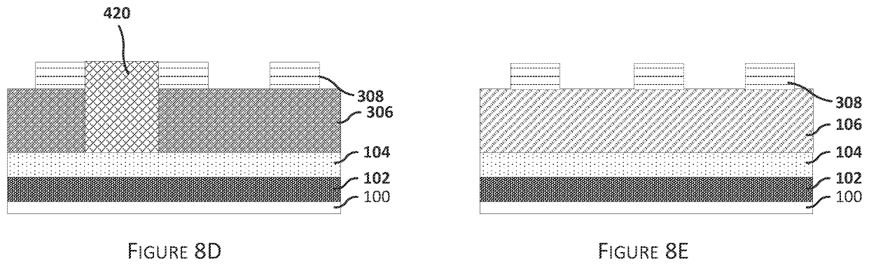

The material of the filling layer 306 is different from the material of the mandrels 106 and the spacers 302 so that a subsequent etch is selective to the filling layer 306 over the mandrels 106 and the spacers 302 (see below, FIGS. 8A-8E). For example, in some embodiments the filling layer 306 comprises glass, a metal oxide, a carbon-based material, metal nitride, silicon, silicon oxide, silicon nitride, silicon carbide, the like, or a combination thereof. The filling layer 306 may be formed with a spin-on technique or the like. However, any suitable materials and methods may be used to form the filling layer 306. The filling layer 306 fills the first trenches 304. After forming the filling layer 306, excess material above the mandrels 106 and spacers 302 may be removed with a suitable planarization process, such as a CMP.

The parallel bars of the mandrels 106, the spacers 302, and the filling layer 306 form a pattern that is subsequently used for forming self-aligned blocks. This is advantageous for reducing edge placement error for metallization patterns with very small pitches (e.g., less than 30 nm).

In other embodiments, the filling layer 306 may be omitted. In these embodiments, the first trenches 304 are left unfilled and the underlying material of the hardmask layer 104 is different from the material of the mandrels 106 and the spacers 302 so that a subsequent etch is selective to the hardmask layer 104 over the mandrels 106 and the spacers 302.

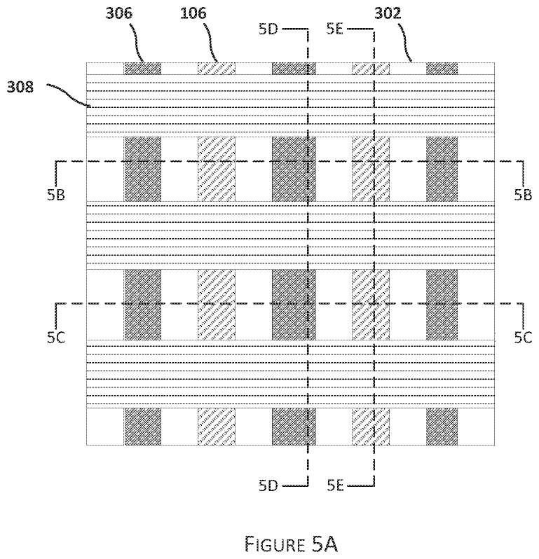

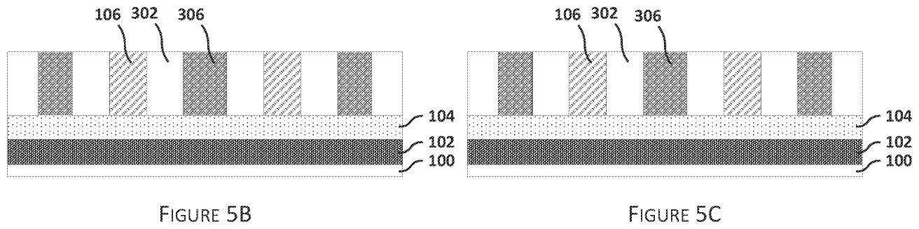

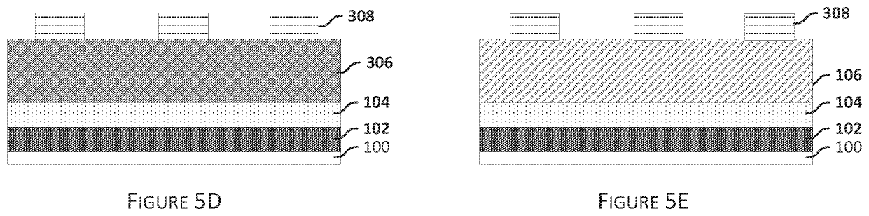

FIGS. 5A-5E illustrate a plan view and respective cross-sectional views of the semiconductor structure after a patterned metal oxide resist 308 is formed over the structure, in accordance with some embodiments. FIG. 5B is illustrated in a cross-sectional view along line 5B-5B in FIG. 5A, FIG. 5C is illustrated in a cross-sectional view along line 5C-5C in FIG. 5A, FIG. 5D is illustrated in a cross-sectional view along line 5D-5D in FIG. 5A, and FIG. 5E is illustrated in a cross-sectional view along line 5E-5E in FIG. 5A.

As shown in FIG. 5A, the rows of the patterned metal oxide resist 308 form a grid pattern with the columns of the mandrels 106, the spacers 302, and the filling layer 306. This allows for the positions of subsequently formed self-aligned blocks to be controlled in both a horizontal direction (in other words, along lines 5B-5B and 5C-5C) and a vertical direction (in other words, along lines 5D-5D and 5E-5E). As the material of the patterned metal oxide resist 308 is different from the respective materials of the mandrels 106, the spacers 302, and the filling layer 306, exposed portions of the filling layer 306 and the mandrels 106 between the bars of the patterned metal oxide resist 308 may be selectively etched and fully self-aligned blocks may be formed in the resulting holes (see below, FIGS. 8A-11E). These fully self-aligned blocks are advantageous for reducing edge placement errors in metallization patterns with very small critical dimensions, such as critical dimensions less than 15 nm.

The patterned metal oxide resist 308 is formed from a metal oxide layer. In some embodiments, the metal oxide layer comprises tin (Sn), antimony (Sb), hafnium (Hf), zirconium (Zr), zinc (Zn), the like, or a combination thereof. In certain embodiments, the metal oxide layer comprises a metal oxide, a metal alkoxide, or a methacrylate (MAA) of Sn, Sb, Hf, Zr, Zn, or the like, such as ZrMAA, SbMAA, SbMAA:F, HfMAA, ZnMAA, and ZnMAA:F. In certain embodiments, the metal oxide layer may be a network of metal oxide comprising a metal alkoxide, metal alkenoxide, metal aryloxide, or metal carboxylate group. These groups bonded to the metal are generally represented by chemical formulas, —OR, —OR′, —OAr, and −OOCR, respectively, where R is an alkyl group, R′ is an alkene group, and Ar is an aryl group. In various embodiments, the metal oxide layer is a polymeric film, and may not have a highly ordered structure such as crystalline. The number of the above functional groups bonded to the metal atom may differ for each metal atom, ranging between 1 and 4. The deposition of the metal oxide layer may be performed by a dry or wet process. In various embodiments, the metal oxide layer may be deposited by vapor deposition, for example chemical vapor deposition (CVD), plasma-enhanced CVD (PECVD), atomic layer deposition (ALD), or plasma-enhanced ALD (PEALD).

The metal oxide layer is then patterned by an exposure to radiation, e.g. extreme ultraviolet (EUV) light and a subsequent development process. The development process may be a dry or wet etch (e.g., a dry process using HBr) that is selective to either the exposed or the unexposed regions of the metal oxide layer. The exposure and development processes form the patterned metal oxide resist 308 with bars oriented perpendicularly to the mandrels 106, the spacers 302, and the filling layer 306.

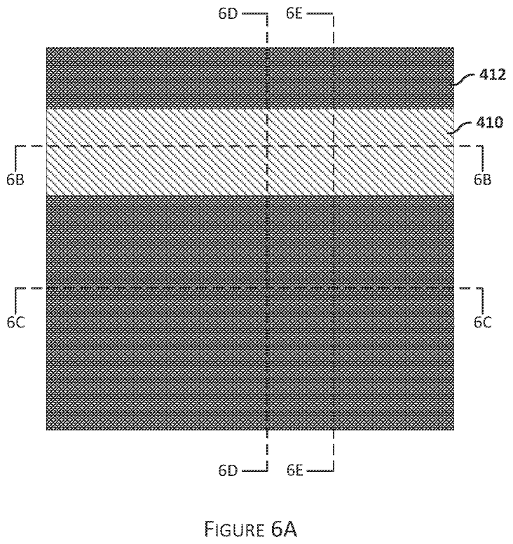

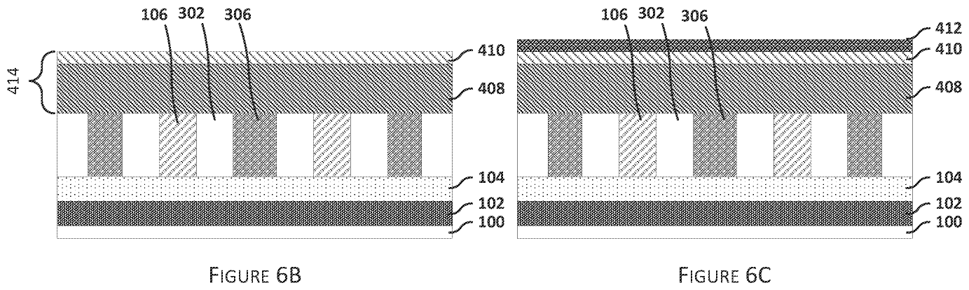

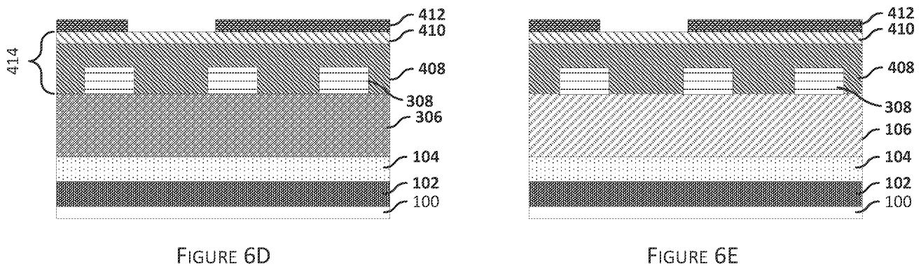

FIGS. 6A-6E illustrate a plan view and respective cross-sectional views of the semiconductor structure after a lithography stack 414 is formed over the structure, in accordance with some embodiments. FIG. 6B is illustrated in a cross-sectional view along line 6B-6B in FIG. 6A, FIG. 6C is illustrated in a cross-sectional view along line 6C-6C in FIG. 6A, FIG. 6D is illustrated in a cross-sectional view along line 6D-6D in FIG. 6A, and FIG. 6E is illustrated in a cross-sectional view along line 6E-6E in FIG. 6A.

The lithography stack 414 is formed over the patterned metal oxide resist 308, the mandrels 106, the spacers 302, and the filling layer 306. In some embodiments, the lithography stack 414 comprises a planarizing layer 408 4and an antireflective coating 410 over the planarizing layer 408. The lithography stack 414 may be formed with similar materials and by similar methods as the lithography stack 114 as described above with respect to FIGS. 1A-1E, and the details are not repeated herein.

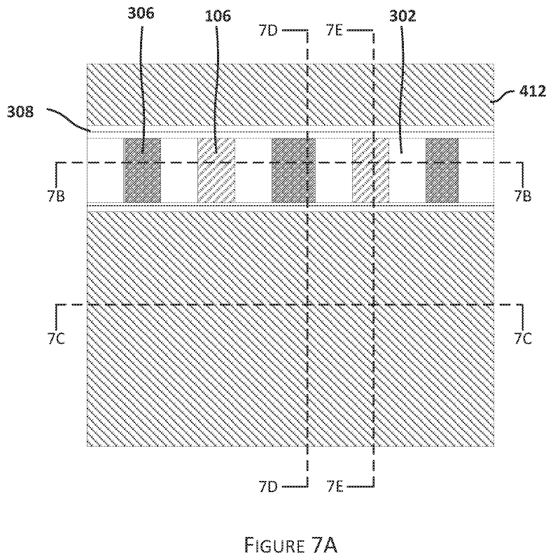

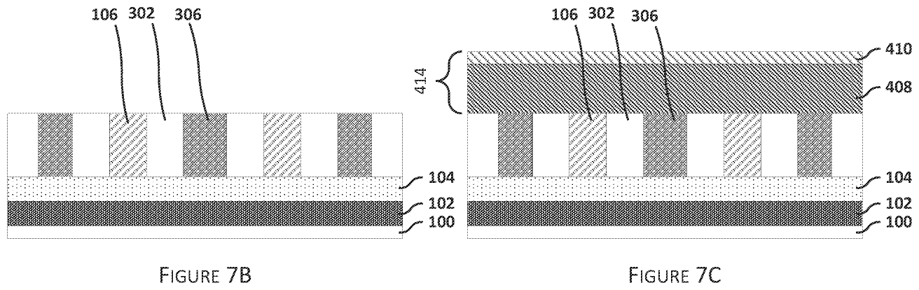

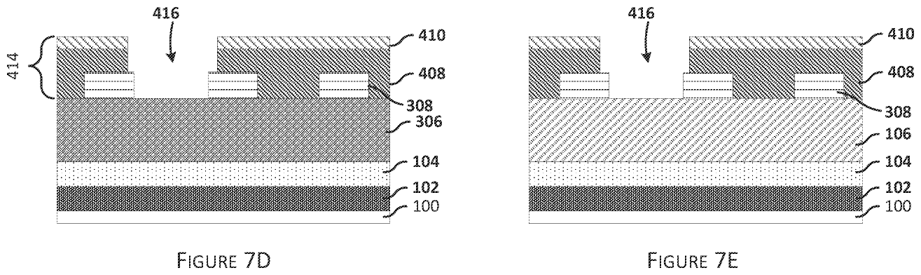

A patterned resist 412 is formed over the lithography stack 414. The patterned resist 412 exposes a portion of the lithography stack 414 overlying a region between adjacent bars of the patterned metal oxide resist 308. The patterned resist 412 is used for the subsequent patterning of the lithography stack 414 in order to form self-aligned blocks (see below, FIGS. 7A-8E). The patterned resist 412 may be formed with similar materials and by similar methods as the patterned resist 112 as described above with respect to FIGS. 1A-1E, and the details are not repeated herein.

FIGS. 7A-7E illustrate a plan view and respective cross-sectional views of the semiconductor structure after the lithography stack 414 is patterned, in accordance with some embodiments. FIG. 7B is illustrated in a cross-sectional view along line 7B-7B in FIG. 7A, FIG. 7C is illustrated in a cross-sectional view along line 7C-7C in FIG. 7A, FIG. 7D is illustrated in a cross-sectional view along line 7D-7D in FIG. 7A, and FIG. 7E is illustrated in a cross-sectional view along line 7E-7E in FIG. 7A.

The lithography stack 414 is patterned to form a second trench 416 exposing a region between neighboring bars of the patterned metal oxide resist 308. In some embodiments, the second trench 416 extends over sidewalls and portions of the top surfaces of the patterned metal oxide resist 308. In other embodiments, sidewalls of the second trench 416 are continuous with sidewalls of the patterned metal oxide resist 308. The lithography stack 414 may be patterned by similar methods as the lithography stack 114 and the patterned resist 412 may be removed by similar methods as the patterned resist 112 as described above with respect to FIGS. 1A-1E, and the details are not repeated herein.

FIGS. 8A-8E illustrate a plan view and respective cross-sectional views of the semiconductor structure after a first self-aligned block layer 420 is formed, in accordance with some embodiments. FIG. 8B is illustrated in a cross-sectional view along line 8B-8B in FIG. 8A, FIG. 8C is illustrated in a cross-sectional view along line 8C-8C in FIG. 8A, FIG. 8D is illustrated in a cross-sectional view along line 8D-8D in FIG. 8A, and FIG. 8E is illustrated in a cross-sectional view along line 8E-8E in FIG. 8A.

After the second trench 416 is formed, portions of the filling layer 306 under the second trench 416 are removed. The resulting holes are confined by the crisscrossing grid of the rows of patterned metal oxide resist 308 and the columns of the spacers 302, which may reduce edge placement error. In other words, the adjacent bars of the patterned metal oxide resist 308 and the spacers 302 are used as an etching mask for forming holes through the filling layer 306. The portions of the filling layer 306 under the second trench 416 may be removed with a suitable dry or wet etching process (e.g., an RIE or the like using anisotropic plasma etching) that is selective to the material of the filling layer 306 over the materials of the patterned metal oxide resist 308, the spacers 302, and the mandrels 106. In some embodiments, an etching selectivity is achieved with a ratio greater than 10:1 of the material of the filling layer 306 with the patterned metal oxide resist 308, the spacers 302, and the mandrel 106.

Next, a first self-aligned block layer 420 is formed in the second trench 416, filling the holes through the filling layer 306. The portions of the first self-aligned block layer 420 formed in the holes through the filling layer 306 have their positions in both a horizontal direction (in other words, along line 8B-8B) and a vertical direction (in other words, along lines 8D-8D and 8E-8E) as shown in FIG. 8A determined by the crisscrossing grid of the patterned metal oxide resist 308 and the spacers 302. As such, the portions of the first self-aligned block layer 420 formed in the holes through the filling layer 306 may be referred to as fully self-aligned blocks, and their edge placement error is reduced in both the horizontal and vertical directions.

In some embodiments, the first self-aligned block layer 420 comprises a dielectric material, e.g., an oxide such as silicon oxide or the like. The first self-aligned block layer 420 may be formed with a suitable process such as a spin-on technique or the like. However, any suitable materials and processes may be used to form the first self-aligned block layer 420.

Although FIGS. 7A-8E illustrate the formation of one second trench 416 and three fully self-aligned blocks of the first self-aligned block layer 420, it should be appreciated that these are non-limiting examples. Any suitable number of second trenches 416 and any suitable number of fully self-aligned blocks may be formed and are within the scope of the disclosed embodiments.

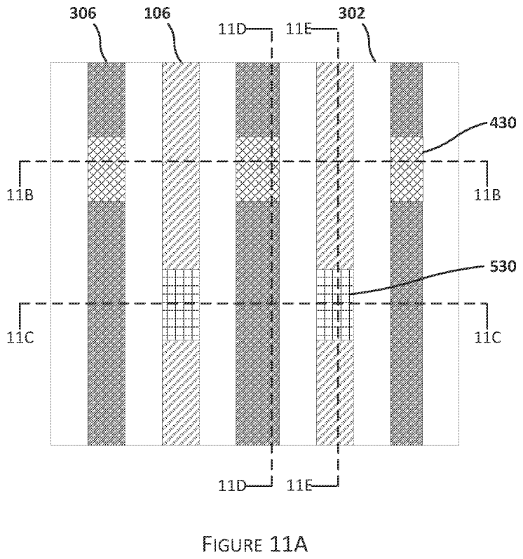

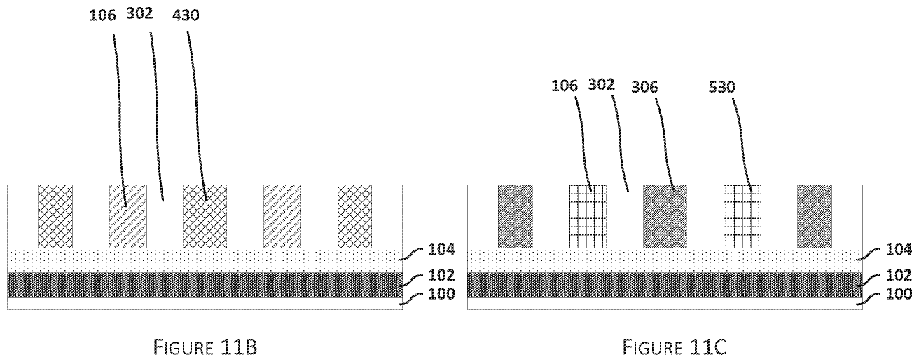

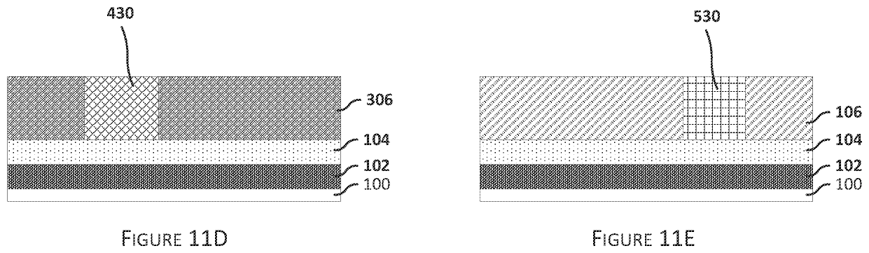

In some embodiments, excess material of the first self-aligned block layer 420 above top surfaces of the spacers 302 and the mandrels 106 remains until a subsequent planarization step (see below, FIGS. 11A-11E). In other embodiments, the excess material of the first self-aligned block layer 420 above top surfaces of the spacers 302 and the mandrels 106 is removed with a suitable process (e.g., a timed etch selective to the material of the first self-aligned block layer 420).

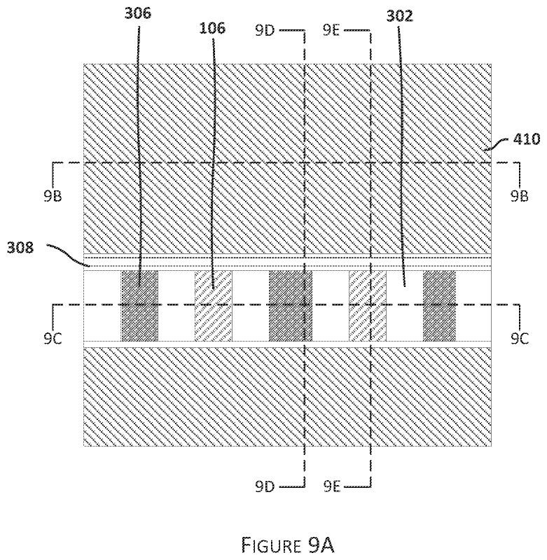

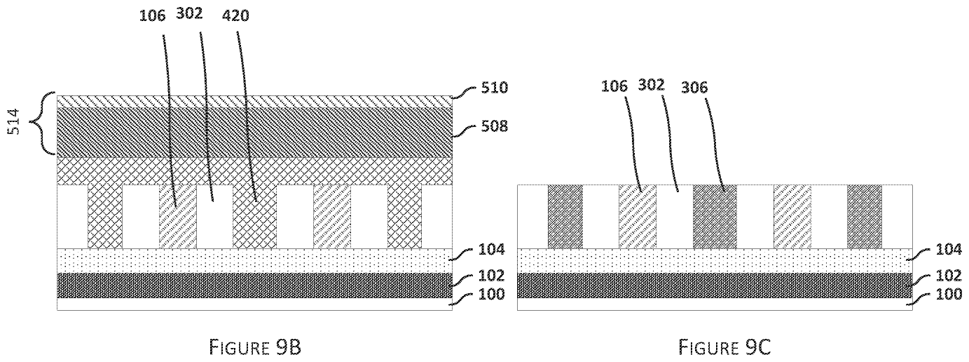

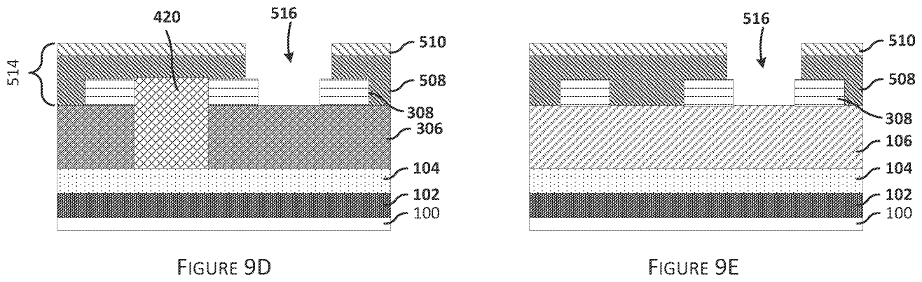

FIGS. 9A-9E illustrate a plan view and respective cross-sectional views of the semiconductor structure after a lithography stack 514 is formed and patterned, in accordance with some embodiments. FIG. 9B is illustrated in a cross-sectional view along line 9B-9B in FIG. 9A, FIG. 9C is illustrated in a cross-sectional view along line 9C-9C in FIG. 9A, FIG. 9D is illustrated in a cross-sectional view along line 9D-9D in FIG. 9A, and FIG. 9E is illustrated in a cross-sectional view along line 9E-9E in FIG. 9A.

The lithography stack 514 may be formed and patterned with similar materials and by similar methods as the lithography stack 414 as described above with respect to FIGS. 6A-7E, and the details are not repeated herein. The lithography stack 514 is patterned to form a third trench 516 exposing a region between neighboring bars of the patterned metal oxide resist 308. In the illustrated example of FIGS. 9A-9E, the third trench 516 is on an opposite side of a bar of the patterned metal oxide resist 308 from the first self-aligned block layer 420. However, one or more third trench(es) may be formed in any suitable location between neighboring bars of the patterned metal oxide resist 308.

FIGS. 10A-10E illustrate a plan view and respective cross-sectional views of the semiconductor structure after a second self-aligned block layer 520 is formed, in accordance with some embodiments. FIG. 10B is illustrated in a cross-sectional view along line 10B-10B in FIG. 10A, FIG. 10C is illustrated in a cross-sectional view along line 10C-10C in FIG. 10A, FIG. 10D is illustrated in a cross-sectional view along line 10D-10D in FIG. 10A, and FIG. 10E is illustrated in a cross-sectional view along line 10E-10E in FIG. 10A.

After the third trench 516 is formed, portions of the mandrels 106 under the third trench 516 are removed. The resulting holes are confined by the crisscrossing grid of the patterned metal oxide resist 308 and the spacers 302, which may reduce edge placement error. In other words, the adjacent bars of the patterned metal oxide resist 308 and the spacers 302 are used as an etching mask for forming holes through the mandrels 106. The portions of the mandrels 106 under the third trench 516 may be removed with a suitable dry or wet etching process (e.g., an RIE or the like using anisotropic plasma etching) that is selective to the material of the mandrels 106 over the materials of the patterned metal oxide resist 308, the spacers 302, and the filling layer 306. In some embodiments, an etching selectivity is achieved with a ratio greater than 10:1 of the material of the filling layer 306 with the patterned metal oxide resist 308, the spacers 302, and the mandrel 106.

Next, a second self-aligned block layer 520 is formed in the third trench 516, filling the holes through the mandrels 106. The second self-aligned block layer 520 may be formed using similar materials and by similar methods as the first self-aligned block layer 420 as described above with respect to FIGS. 8A-8E, and the details are not repeated herein. The portions of the second self-aligned block layer 520 formed in the holes through the mandrels 106 have their positions in both a horizontal direction (in other words, along line 10C-10C) and a vertical direction (in other words, along lines 10D-10D and 10E-10E) as shown in FIG. 10A determined by the crisscrossing grid of the patterned metal oxide resist 308 and the spacers 302. As such, the portions of the second self-aligned block layer 520 formed in the holes through the mandrels 106 may be referred to as fully self-aligned blocks, and their edge placement error is reduced in both the horizontal and vertical directions.

Although FIGS. 9A-10E illustrate the formation of one third trench 516 and two fully self-aligned blocks of the second self-aligned block layer 520, it should be appreciated that these are non-limiting examples. Any suitable number of third trenches 516 and any suitable number of fully self-aligned blocks may be formed and are within the scope of the disclosed embodiments.

In some embodiments, excess material of the second self-aligned block layer 520 above top surfaces of the spacers 302 and the filling layer 306 remains until a subsequent planarization step (see below, FIGS. 11A-11E). In other embodiments, the excess material of the second self-aligned block layer 520 above top surfaces of the spacers 302 and the filling layer 306 is removed with a suitable process (e.g., a timed etch selective to the material of the second self-aligned block layer 520).

FIGS. 11A-11E illustrate a plan view and respective cross-sectional views of the semiconductor structure after the patterned metal oxide resist 308 is removed, in accordance with some embodiments. FIG. 11B is illustrated in a cross-sectional view along line 11B-11B in FIG. 11A, FIG. 11C is illustrated in a cross-sectional view along line 11C-11C in FIG. 11A, FIG. 11D is illustrated in a cross-sectional view along line 11D-11D in FIG. 11A, and FIG. 11E is illustrated in a cross-sectional view along line 11E-11E in FIG. 11A.

The patterned metal oxide resist 308 and excess material of the first self-aligned block layer 420 and the second self-aligned block layer 520 (if present) are removed with one or more suitable planarization processes (e.g., a CMP or the like) or etching processes (e.g., an RIE selective to the patterned metal oxide resist 308). Remaining portions of the first self-aligned block layer 420 and the second self-aligned block layer 520 form first self-aligned blocks 430 and second self-aligned blocks 530, respectively. Top surfaces of the first self-aligned blocks 430, the second self-aligned blocks 530, the mandrels 106, the spacers 302, and the filling layer 306 may be coplanar. In the example illustrated by FIGS. 11A-11E, three first self-aligned blocks 430 and two second self-aligned blocks 530 are present. However, any suitable numbers of three first self-aligned blocks 430 and second self-aligned blocks 530 may be formed.

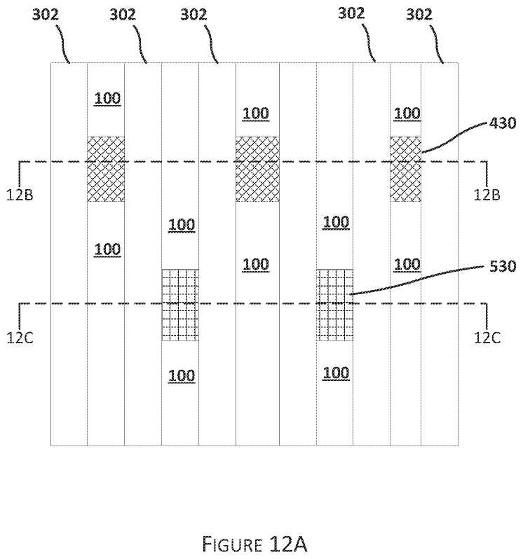

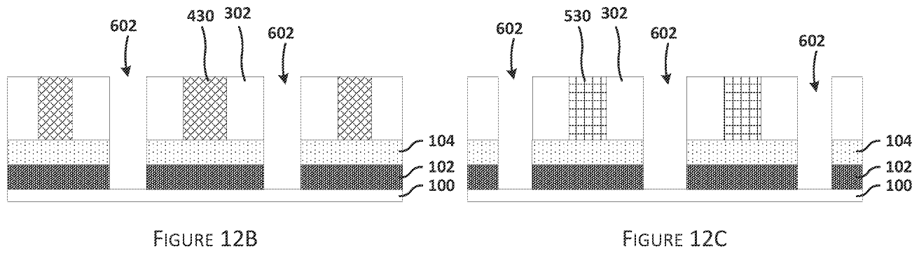

FIGS. 12A-12E illustrate a plan view and respective cross-sectional views of the semiconductor structure after the target layer 102 is patterned, in accordance with some embodiments. FIG. 12B is illustrated in a cross-sectional view along line 12B-12B in FIG. 12A, FIG. 12C is illustrated in a cross-sectional view along line 12C-12C in FIG. 12A, FIG. 12D is illustrated in a cross-sectional view along line 12D-12D in FIG. 12A, and FIG. 12E is illustrated in a cross-sectional view along line 12E-12E in FIG. 12A.

The target layer 102 is patterned in order to subsequently form a metallization pattern (see below, FIGS. 13A-13C). The mandrels 106 and the filling layer 306 are removed with one or more etching processes selective to the respective materials of the mandrels 106 and the filling layer 306 to form a pattern of fourth trenches 602. Next, the spacers 302, the first self-aligned blocks 430, and the second self-aligned blocks 530 are used as an etching mask in an etching process (e.g., a wet or dry process) to extend the pattern of fourth trenches 602 through the hardmask layer 104 and the target layer 102. In various embodiments, the mandrels 106, the filling layer 306, and the exposed portions of the hardmask layer 104 and the target layer 102. In various embodiments, each of the mandrels 106, the filling layer 306, =and the exposed portions of the hardmask layer 104 and the target layer 102 may be removed with respective one or more etching processes. In various embodiments, two or more of the mandrels 106, the filling layer 306, and the exposed portions of the hardmask layer 104 and the target layer 102 are removed with respective single etching processes.

FIGS. 13A-13C illustrate a plan view and respective cross-sectional views of the semiconductor structure after a metallization pattern 604 is formed, in accordance with some embodiments. FIG. 13B is illustrated in a cross-sectional view along line 13B-13B in FIG. 13A, and FIG. 13C is illustrated in a cross-sectional view along line 13C-13C in FIG. 13A.

After the target layer 102 is patterned by forming the fourth trenches 602 through the target layer 102 (see above, FIGS. 12A-12E), remaining portions of the spacers 302, the first self-aligned blocks 430, the second self-aligned block 530, and the hardmask layer 104 may be removed with a suitable process, e.g. a CMP. The metallization pattern 604 is then formed in the fourth trenches 602 through the target layer 102. As an example of forming the metallization pattern 604, the fourth trenches 602 are filled with a conductive material such as a metal. For example, the conductive material may be copper formed using electroplating. However, any suitable conductive material (e.g., tungsten, cobalt, ruthenium, the like, or a combination thereof) and deposition method (e.g., ALD, PVD, or the like) may be used. Excess conductive material formed over a top surface of the target layer 102 may be removed with a suitable process, e.g. a CMP.

The resulting metallization pattern 604 may have critical dimensions (in other words, spacings between conductive lines of the metallization pattern 604) less than 15 nm. Using the fully self-aligned blocks 430 and 530 (see above, FIGS. 12A-12E) is advantageous by reducing edge placement error, which may increase product yield.

FIG. 14 illustrates a process flow chart diagram of a method 700 for patterning a substrate 100, in accordance with some embodiments. In step 702, a first line (e.g., a spacer 302), a second line (e.g., a mandrel 106), and a third line (e.g., a spacer 302) are formed over the substrate 100, as described above with respect to FIGS. 2A-3E. The second line is between the first line and the third line. The first line and the third line are a first material and the second line is a second material, the second material being different from the first material. The first line, the second line, and the third line are parallel in a plan view.

In step 704, a fourth line (e.g., a bar of a patterned metal oxide resist 308) and a fifth line (e.g., another bar of a patterned metal oxide resist 308) are formed over the first line, the second line, and the third line, as described above with respect to FIGS. 5A-5E. The fourth line and the fifth line are a third material that is different from the first material and the second material. The fourth line and the fifth line are orthogonal to the first line in the plan view.

In step 706, a hole is etched through the second line using the first line, the third line, the fourth line, and the fifth line as an etching mask, as described above with respect to FIGS. 10A-10E. In step 708, the hole is filled with a dielectric material (e.g., a self-aligned block layer 520) to form a block (e.g., a self-aligned block 530), as described above with respect to FIGS. 10A-11E.

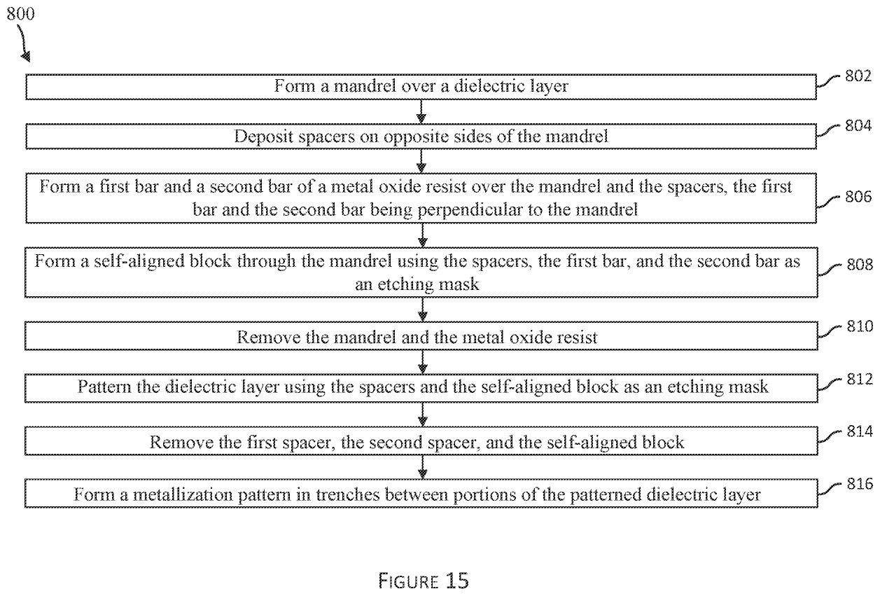

FIG. 15 illustrates a process flow chart diagram of another method 800 for patterning a substrate 100, in accordance with some embodiments. In step 802, a mandrel 106 is formed over a dielectric layer (e.g., a target layer 102), as described above with respect to FIGS. 2A-2E. In step 804, a first spacer (e.g., a spacer 302) is deposited on a first side of the mandrel 106 and a second spacer (e.g., a spacer 302) is deposited on a second side of the mandrel 106, the second side being opposite the first side, as described above with respect to FIGS. 3A-3E.

In step 806, a metal oxide resist (e.g., a patterned metal oxide resist 308) is formed over the mandrel 106, the first spacer, and the second spacer, as described above with respect to FIGS. 5A-5E. The metal oxide resist comprises a first bar and a second bar that are perpendicular to the mandrel 106 in a plan view.

In step 808, a self-aligned block 530 is formed through the mandrel 106 using the first spacer, the second spacer, the first bar of the metal oxide resist, and the second bar of the metal oxide resist as an etching mask, as described above with respect to FIGS. 10A-11E. In step 810, the mandrel 106 and the metal oxide resist are removed, as described above with respect to FIGS. 11A-11E.

In step 812, the dielectric layer is patterned using the first spacer, the second spacer, and the self-aligned block 530 as an etching mask, as described above with respect to FIGS. 12A-12E. In step 814, the first spacer, the second spacer, and the self-aligned block 530 are removed, as described above with respect to FIGS. 13A-13C. In step 814, a metallization pattern 604 is formed in trenches (e.g., fourth trenches 602) between portions of the patterned dielectric layer, as described above with respect to FIGS. 13A-13C.

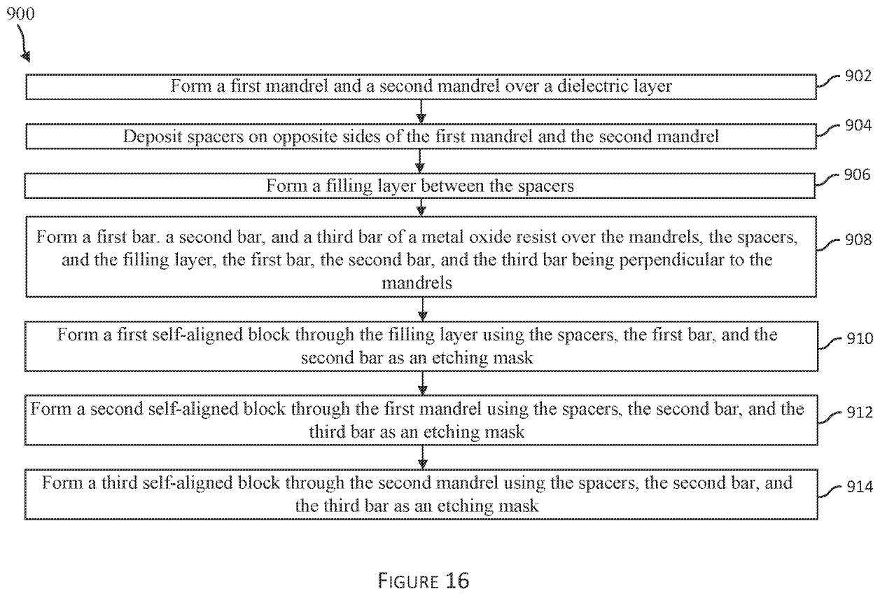

FIG. 16 illustrates a process flow chart diagram of yet another method 900 for patterning a substrate 100, in accordance with some embodiments. In step 902, a first mandrel (e.g., a mandrel 106) and a second mandrel (e.g., a mandrel 106) are formed over a dielectric layer (e.g., a target layer 102), as described above with respect to FIGS. 2A-2E. In step 904, a first spacer (e.g, a spacer 302) and a second spacer (e.g, a spacer 302) are deposited on opposite sides of the first mandrel, and a third spacer (e.g, a spacer 302) and a fourth spacer (e.g, a spacer 302) are deposited on opposite sides of the second mandrel, as described above with respect to FIGS. 3A-3E.

In step 906, a filling layer 306 is formed between the second spacer and the third spacer, as described above with respect to FIGS. 4A-4E. In step 908, a metal oxide resist (e.g., a patterned metal oxide resist 308) is formed over the first mandrel, the second mandrel, the first spacer, the second spacer, the third spacer, the fourth spacer, and the filling layer 306, as described above with respect to FIGS. 5A-5E. The metal oxide resist comprises a first bar, a second bar, and a third bar that are perpendicular to the first mandrel and the second mandrel in a plan view.

In step 910, a first self-aligned block 430 is formed through the filling layer 306 using the second spacer, the third spacer, the first bar of the metal oxide resist, and the second bar of the metal oxide resist as an etching mask, as described above with respect to FIGS. 8A-8E and 11A-11E. In step 912, a second self-aligned block 530 is formed through the first mandrel using the first spacer, the second spacer, the second bar of the metal oxide resist, and the third bar of the metal oxide resist as an etching mask, as described above with respect to FIGS. 10A-11E. In step 914, a third self-aligned block (e.g., a second self-aligned block 530) is formed through the second mandrel using the third spacer, the fourth spacer, the second bar of the metal oxide resist, and the third bar of the metal oxide resist as an etching mask, as described above with respect to FIGS. 10A-11E.

Example embodiments of the disclosure are summarized here. Other embodiments can also be understood from the entirety of the specification as well as the claims filed herein.

Example 1. A method of patterning a substrate, the method including: forming a first line, a second line, and a third line over the substrate, where the second line is between the first line and the third line, where the first line and the third line are a first material, where the second line is a second material, the second material being different from the first material, and where the first line, the second line, and the third line are parallel in a plan view; forming a fourth line and a fifth line over the first line, the second line, and the third line, the fourth line and the fifth line being orthogonal to the first line in the plan view, where the fourth line and the fifth line are a third material, the third material being different from the first material and the second material; etching a hole through the second line using the first line, the third line, the fourth line, and the fifth line as an etching mask; and filling the hole with a dielectric material to form a block.

Example 2. The method of example 1, where the third material includes a metal oxide.

Example 3. The method of one of examples 1 or 2, where forming the fourth line and the fifth line includes exposing the third material to extreme ultraviolet radiation.

Example 4. The method of one of examples 1 to 3, further including removing the second line, the fourth line, and the fifth line.

Example 5. The method of example 4, further including patterning a dielectric layer of the substrate using the block, the first line, and the third line as an etching mask.

Example 6. The method of example 5, further including: removing the block, the first line, and the third line; and forming a conductive material in trenches between portions of the patterned dielectric layer.

Example 7. The method of one of examples 1 to 6, where the first material includes an oxide or a nitride.

Example 8. The method of one of examples 1 to 7, where the second material includes amorphous silicon or amorphous carbon.

Example 9. A method of patterning a substrate, the method including: forming a mandrel over a dielectric layer; depositing a first spacer on a first side of the mandrel and a second spacer on a second side of the mandrel, the second side being opposite the first side; forming a metal oxide resist over the mandrel, the first spacer, and the second spacer, the metal oxide resist including a first bar and a second bar, the first bar and the second bar being perpendicular to the mandrel in a plan view; forming a self-aligned block through the mandrel using the first spacer, the second spacer, the first bar of the metal oxide resist, and the second bar of the metal oxide resist as an etching mask; removing the mandrel and the metal oxide resist; patterning the dielectric layer using the first spacer, the second spacer, and the self-aligned block as an etching mask; removing the first spacer, the second spacer, and the self-aligned block; and forming a metallization pattern in trenches between portions of the patterned dielectric layer.

Example 10. The method of example 9, where forming the metal oxide resist includes exposing a metal oxide to extreme ultraviolet light.

Example 11. The method of one of examples 9 or 10, where the first spacer and the second spacer include silicon oxide, silicon nitride, titanium nitride, titanium oxide, or zirconium oxide.

Example 12. The method of one of examples 9 to 11, where the mandrel includes amorphous carbon.

Example 13. The method of one of examples 9 to 12, where the self-aligned block includes silicon oxide.

Example 14. The method of one of examples 9 to 13, where the self-aligned block is formed with a spin-on technique.

Example 15. A method of patterning a substrate, the method including: forming a first mandrel and a second mandrel over a dielectric layer; depositing a first spacer and a second spacer on opposite sides of the first mandrel and depositing a third spacer and a fourth spacer on opposite sides of the second mandrel; forming a filling layer between the second spacer and the third spacer; forming a metal oxide resist over the first mandrel, the second mandrel, the first spacer, the second spacer, the third spacer, and the fourth spacer, the metal oxide resist including a first bar, a second bar, and a third bar, the first bar, the second bar, and the third bar being perpendicular to the first mandrel in a plan view; forming a first self-aligned block through the filling layer using the second spacer, the third spacer, the first bar of the metal oxide resist, and the second bar of the metal oxide resist as an etching mask; forming a second self-aligned block through the first mandrel using the first spacer, the second spacer, the second bar of the metal oxide resist, and the third bar of the metal oxide resist as an etching mask; and forming a third self-aligned block through the second mandrel using the third spacer, the fourth spacer, the second bar of the metal oxide resist, and the third bar of the metal oxide resist as an etching mask.

Example 16. The method of example 15, further including: removing the first mandrel, the second mandrel, the filling layer, and the metal oxide resist; and patterning the dielectric layer using the first spacer, the second spacer, the third spacer, the fourth spacer, the first self-aligned block, the second self-aligned block, and the third self-aligned block as an etching mask.

Example 17. The method of example 16, further including: removing the first spacer, the second spacer, the third spacer, the fourth spacer, the first self-aligned block, the second self-aligned block, and the third self-aligned block; and forming a metallization pattern in trenches between portions of the patterned dielectric layer.

Example 18. The method of one of examples 15 to 17, where forming the metal oxide resist includes: forming a metal oxide layer; exposing the metal oxide layer to extreme ultraviolet radiation; and developing the metal oxide layer.

Example 19. The method of one of examples 15 to 18, where the filling layer includes glass or metal oxide.

Example 20. The method of one of examples 15 to 19, where the filling layer is formed using a spin-on technique.

Although the description has been described in detail, it should be understood that various changes, substitutions, and alterations may be made without departing from the spirit and scope of this disclosure as defined by the appended claims. The same elements are designated with the same reference numbers in the various figures. Moreover, the scope of the disclosure is not intended to be limited to the particular embodiments described herein, as one of ordinary skill in the art will readily appreciate from this disclosure that processes, machines, manufacture, compositions of matter, means, methods, or steps, presently existing or later to be developed, may perform substantially the same function or achieve substantially the same result as the corresponding embodiments described herein. Accordingly, the appended claims are intended to include within their scope such processes, machines, manufacture, compositions of matter, means, methods, or steps.

What is claimed is:

1. A method of patterning a substrate, the method comprising:
forming a first line, a second line, and a third line over the substrate, wherein the second line is between the first line and the third line, wherein the first line and the third line are a first material, wherein the second line is a second material, the second material being different from the first material, and wherein the first line, the second line, and the third line are parallel in a plan view;
forming a fourth line and a fifth line over the first line, the second line, and the third line, the fourth line and the fifth line being orthogonal to the first line in the plan view, wherein the fourth line and the fifth line are a third material, the third material being different from the first material and the second material;
etching a hole through the second line using the first line, the third line, the fourth line, and the fifth line as an etching mask; and
filling the hole with a dielectric material to form a block.

2. The method of claim 1, wherein the third material comprises a metal oxide.

3. The method of claim 1, wherein forming the fourth line and the fifth line comprises exposing the third material to extreme ultraviolet radiation.

4. The method of claim 1, further comprising removing the second line, the fourth line, and the fifth line.

5. The method of claim 4, further comprising patterning a dielectric layer of the substrate using the block, the first line, and the third line as an etching mask.

6. The method of claim 5, further comprising:
removing the block, the first line, and the third line; and
forming a conductive material in trenches between portions of the patterned dielectric layer.

7. The method of claim 1, wherein the first material comprises an oxide or a nitride.

8. The method of claim 1, wherein the second material comprises amorphous silicon or amorphous carbon.

9. A method of patterning a substrate, the method comprising:
forming a mandrel over a dielectric layer;
depositing a first spacer on a first side of the mandrel and a second spacer on a second side of the mandrel, the second side being opposite the first side;
forming a metal oxide resist over the mandrel, the first spacer, and the second spacer, the metal oxide resist comprising a first bar and a second bar, the first bar and the second bar being perpendicular to the mandrel in a plan view;
forming a self-aligned block through the mandrel using the first spacer, the second spacer, the first bar of the metal oxide resist, and the second bar of the metal oxide resist as an etching mask;
removing the mandrel and the metal oxide resist;
patterning the dielectric layer using the first spacer, the second spacer, and the self-aligned block as an etching mask;
removing the first spacer, the second spacer, and the self-aligned block; and
forming a metallization pattern in trenches between portions of the patterned dielectric layer.

10. The method of claim 9, wherein forming the metal oxide resist comprises exposing a metal oxide to extreme ultraviolet light.

11. The method of claim 9, wherein the first spacer and the second spacer comprise silicon oxide, silicon nitride, titanium nitride, titanium oxide, or zirconium oxide.

12. The method of claim 9, wherein the mandrel comprises amorphous carbon.

13. The method of claim 9, wherein the self-aligned block comprises silicon oxide.

14. The method of claim 9, wherein the self-aligned block is formed with a spin-on technique.

15. A method of patterning a substrate, the method comprising:
forming a first mandrel and a second mandrel over a dielectric layer;
depositing a first spacer and a second spacer on opposite sides of the first mandrel and depositing a third spacer and a fourth spacer on opposite sides of the second mandrel;
forming a filling layer between the second spacer and the third spacer;
forming a metal oxide resist over the first mandrel, the second mandrel, the first spacer, the second spacer, the third spacer, and the fourth spacer, the metal oxide resist comprising a first bar, a second bar, and a third bar, the first bar, the second bar, and the third bar being perpendicular to the first mandrel in a plan view;
forming a first self-aligned block through the filling layer using the second spacer, the third spacer, the first bar of the metal oxide resist, and the second bar of the metal oxide resist as an etching mask;
forming a second self-aligned block through the first mandrel using the first spacer, the second spacer, the second bar of the metal oxide resist, and the third bar of the metal oxide resist as an etching mask; and
forming a third self-aligned block through the second mandrel using the third spacer, the fourth spacer, the second bar of the metal oxide resist, and the third bar of the metal oxide resist as an etching mask.

16. The method of claim 15, further comprising: removing the first mandrel, the second mandrel, the filling layer, and the metal oxide resist; and
patterning the dielectric layer using the first spacer, the second spacer, the third spacer, the fourth spacer, the first self-aligned block, the second self-aligned block, and the third self-aligned block as an etching mask.

17. The method of claim 16, further comprising:
removing the first spacer, the second spacer, the third spacer, the fourth spacer, the first self-aligned block, the second self-aligned block, and the third self-aligned block; and
forming a metallization pattern in trenches between portions of the patterned dielectric layer.

18. The method of claim 15, wherein forming the metal oxide resist comprises:
forming a metal oxide layer;
exposing the metal oxide layer to extreme ultraviolet radiation; and
developing the metal oxide layer.

19. The method of claim 15, wherein the filling layer comprises glass or metal oxide.

20. The method of claim 15, wherein the filling layer is formed using a spin-on technique.
